(19) United States
(12) Patent Application Publication
(10) Pub. No.: US 2025/0300131 A1
(43) Pub. Date: Sep. 25, 2025

(54) PACKAGE STRUCTURE AND METHOD OF FABRICATING THE SAME

(71) Applicant: Taiwan Semiconductor Manufacturing Company, Ltd., Hsinchu (TW)

(72) Inventors: Chia-Kuei Hsu, Hsinchu City (TW); Ming-Chih Yew, Hsinchu City (TW); Tsung-Yen Lee, Changhua County (TW); Shin-Puu Jeng, Hsinchu (TW)

(73) Assignee: Taiwan Semiconductor Manufacturing Company, Ltd., Hsinchu (TW)

(21) Appl. No.: 18/610,281

(22) Filed: Mar. 20, 2024

(51) Int. Cl. H01L 25/065; H01L 21/56; H01L 23/00; H01L 23/31; H01L 25/00; H01L 25/16

(52) U.S. Cl. CPC H01L 25/0655; H01L 21/561; H01L 21/563; H01L 23/3128; H01L 23/3135; H01L 23/3185; H01L 23/3192; H01L 24/13; H01L 24/16; H01L 24/32; H01L 24/73; H01L 24/81; H01L 24/83; H01L 24/92; H01L 24/95; H01L 25/162; H01L 25/50; H01L 21/568; H01L 2224/13147; H01L 2224/16227; H01L 2224/32137; H01L 2224/32225; H01L 2224/73204; H01L 2224/81005; H01L 2224/81192; H01L 2224/81815; H01L 2224/83005; H01L 2224/92125; H01L 2224/95001; H01L 2924/1432; H01L 2924/1433; H01L 2924/1436; H01L 2924/1437

(57) ABSTRACT

A package structure includes first semiconductor dies, second semiconductor dies, electrical connectors, an interconnection layer and an underfill structure. The first semiconductor dies are embedded in an insulating encapsulant, wherein backside surfaces of the first semiconductor dies are revealed by the insulating encapsulant. The second semiconductor dies are embedded in corners of the insulating encapsulant, wherein backside surfaces of the second semiconductor dies are covered by the insulating encapsulant. The electrical connectors are disposed on the first semiconductor dies and the second semiconductor dies. The interconnection layer is disposed on the insulating encapsulant and electrically connected to the first semiconductor dies and the second semiconductor dies through the electrical connectors. The underfill structure is disposed in between the first semiconductor dies, the second semiconductor dies and the interconnection layer, and laterally surrounding the electrical connectors.

### BACKGROUND

Semiconductor devices and integrated circuits used in a variety of electronic applications, such as cell phones and other mobile electronic equipment, are typically manufactured on a single semiconductor wafer. The dies of the wafer may be processed and packaged with other semiconductor devices or dies at the wafer level, and various technologies have been developed for the wafer level packaging.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the critical dimensions of the various features may be arbitrarily increased or reduced for clarity of discussion.

FIG. 1 to FIG. 12B are schematic sectional and top views of various stages in a method of fabricating a package structure according to some exemplary embodiments of the present disclosure.

FIG. 13A and FIG. 13B are schematic sectional and top views of a package structure according to some other exemplary embodiments of the present disclosure.

FIG. 14A and FIG. 14B are schematic sectional and top views of a package structure according to some other exemplary embodiments of the present disclosure.

FIG. 15 is a schematic sectional view of a package structure according to some other exemplary embodiments of the present disclosure.

FIG. 16 is a schematic sectional view of a package structure according to some other exemplary embodiments of the present disclosure.

FIG. 17A and FIG. 17B are schematic sectional and top views of a package structure according to some other exemplary embodiments of the present disclosure.

FIG. 18A and FIG. 18B are schematic sectional and top views of a package structure according to some other exemplary embodiments of the present disclosure.

FIG. 19 is a schematic sectional view of a package structure according to some other exemplary embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a second feature over or on a first feature in the description that follows may include embodiments in which the second and first features are formed in direct contact, and may also include embodiments in which additional features may be formed between the second and first features, such that the second and first features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath”, “below”, “lower”, “on”, “over”, “overlying”, “above”, “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

In current applications, semiconductor packages usually include a plurality of semiconductor dies embedded in an insulating encapsulant, whereby a planarization or grinding process is performed to reveal the backside surfaces of the semiconductor dies from the insulating encapsulant. These semiconductor dies usually have a die height that is substantially equal to the insulating encapsulant. However, when such semiconductor dies are located at corners of the packages, molding stress may occur due to an increased substrate contraction force, which may further increase a risk of molding delamination. In some embodiments of the present disclosure, a die thickness of the semiconductor dies located at corners of the semiconductor packages are reduced to improve the reliability of the package structure.

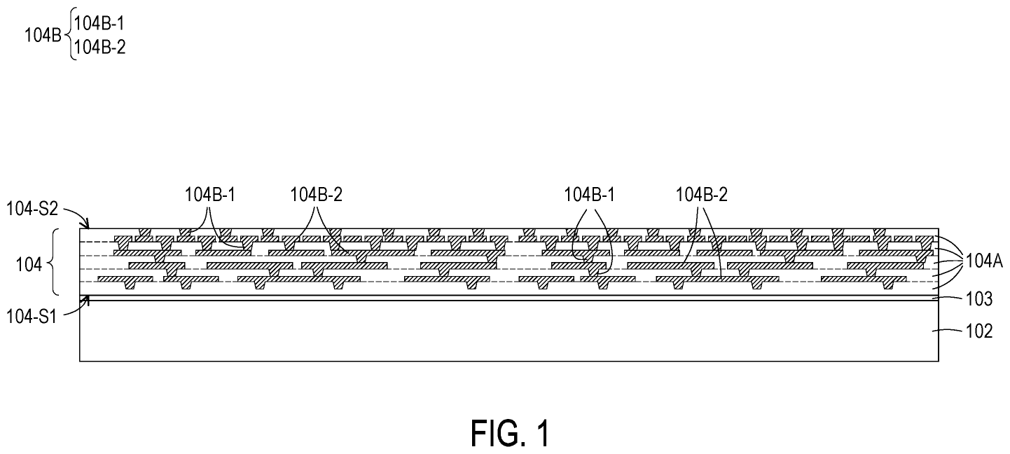

FIG. 1 to FIG. 12B are schematic sectional and top views of various stages in a method of fabricating a package structure according to some exemplary embodiments of the present disclosure. Referring to FIG. 1, a first carrier 102 is provided. In some embodiments, the first carrier 102 may be a glass carrier or any suitable carrier for carrying a semiconductor wafer or a reconstituted wafer for the manufacturing method of the package structure. In some embodiments, the first carrier 102 is coated with a debond layer 103. The material of the debond layer 103 may be any material suitable for bonding and de-bonding the first carrier 102 from the above layer(s) or any wafer(s) disposed thereon.

In some embodiments, the debond layer 103 may include a dielectric material layer made of a dielectric material including any suitable polymer-based dielectric material (such as benzocyclobutene (“BCB”), polybenzoxazole (“PBO”)). In an alternative embodiment, the debond layer 103 may include a dielectric material layer made of an epoxy-based thermal-release material, which loses its adhesive property when heated, such as a light-to-heat-conversion (LTHC) release coating film. In a further alternative embodiment, the debond layer 103 may include a dielectric material layer made of an ultra-violet (UV) glue, which loses its adhesive property when exposed to UV lights. In certain embodiments, the debond layer 103 may be dispensed as a liquid and cured, or may be a laminate film laminated onto the first carrier 102, or may be the like. The top surface of the debond layer 103, which is opposite to a bottom surface contacting the first carrier 102, may be levelled and may have a high degree of coplanarity. In certain embodiments, the debond layer 103 is, for example, a LTHC layer with good chemical resistance, and such layer enables room temperature de-bonding from the first carrier 102 by applying laser irradiation, however the disclosure is not limited thereto.

In an alternative embodiment, a buffer layer (not shown) may be coated on the debond layer 103, where the debond layer 103 is sandwiched between the buffer layer and the first carrier 102, and the top surface of the buffer layer may further provide a high degree of coplanarity. In some embodiments, the buffer layer may be a dielectric material layer. In some embodiments, the buffer layer may be a polymer layer which made of polyimide, PBO, BCB, or any other suitable polymer-based dielectric material. In some embodiments, the buffer layer may be Ajinomoto Buildup Film (ABF), Solder Resist film (SR), or the like. In other words, the buffer layer is optional and may be omitted based on the demand, so that the disclosure is not limited thereto.

As further illustrated in FIG. 1, an interconnection layer 104 is formed on the first carrier 102 over the debond layer 103. In the exemplary embodiment, the interconnection layer 104 is a redistribution layer, and includes a first surface 104-S1 and a second surface 104-S2 opposite to the first surface 104-S2. The interconnection layer 104 is formed on the debond layer 103 by directly attaching its first surface 104-S1 to a surface of the debond layer 103. In some embodiments, the formation of the interconnection layer 104 includes sequentially forming one or more dielectric layers 104A, and one or more conductive layers 104B in alternation. In certain embodiments, the conductive layers 104B includes a plurality of conductive vias 104B-1 and a plurality of conductive lines 104B-2 formed on the plurality of conductive vias 104B-1. Although only five layers of the conductive layers 104B and five layers of dielectric layers 104A are illustrated herein, however, the scope of the disclose is not limited by the embodiments of the disclosure. In some other embodiments, the number of conductive layers 104B and the dielectric layers 104A may be adjusted based on product requirement.

In some embodiments, the material of the dielectric layers 104A may be polyimide, polybenzoxazole (PBO), benzocyclobutene (BCB), a nitride such as silicon nitride, an oxide such as silicon oxide, phosphosilicate glass (PSG), borosilicate glass (BSG), boron-doped phosphosilicate glass (BPSG), a combination thereof or the like, which may be patterned using a photolithography and/or etching process. In some embodiments, the dielectric layers 104A are formed by suitable fabrication techniques such as spin-on coating, chemical vapor deposition (CVD), plasma-enhanced chemical vapor deposition (PECVD) or the like. The disclosure is not limited thereto.

In some embodiments, the material of the conductive elements 104B may be made of conductive materials formed by electroplating or deposition, such as aluminum, titanium, copper, nickel, tungsten, and/or alloys thereof, which may be patterned using a photolithography and etching process. In some embodiments, the conductive elements 104B may be patterned copper layers or other suitable patterned metal layers. Throughout the description, the term “copper” is intended to include substantially pure elemental copper, copper containing unavoidable impurities, and copper alloys containing minor amounts of elements such as tantalum, indium, tin, zinc, manganese, chromium, titanium, germanium, strontium, platinum, magnesium, aluminum or zirconium, etc.

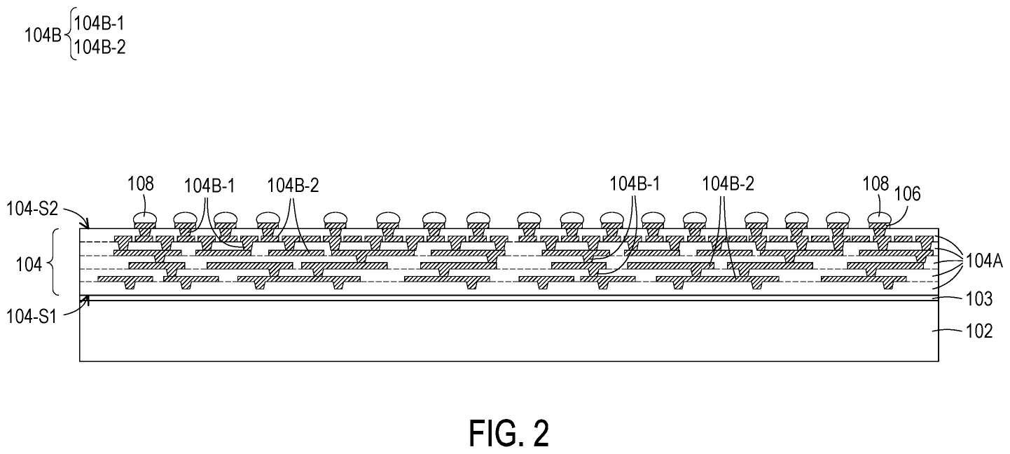

Referring to FIG. 2, after forming the interconnection layer 104, a plurality of conductive pads 106 are formed on an exposed top surface of a topmost layer of the conductive layers 104B of the interconnection layer 104. For example, the conductive pads 106 are disposed on and electrically connected to the conductive layers 104B. In some embodiments, the materials of the conductive pads 106 may include copper, nickel, titanium, tungsten, or alloys thereof or the like, and may be formed by an electroplating process, a deposition process, or the like. After forming the conductive pads 106, a plurality of electrical connectors 108 are formed on the conductive pads 106. In one embodiment, the electrical connectors 108 are micro-bumps, such as micro-bumps having copper metal pillars. In another embodiment, the electrical connectors 108 are solder bumps, lead-free solder bumps, or micro bumps, such as controlled collapse chip connection (C4) bumps or micro bumps containing copper pillars.

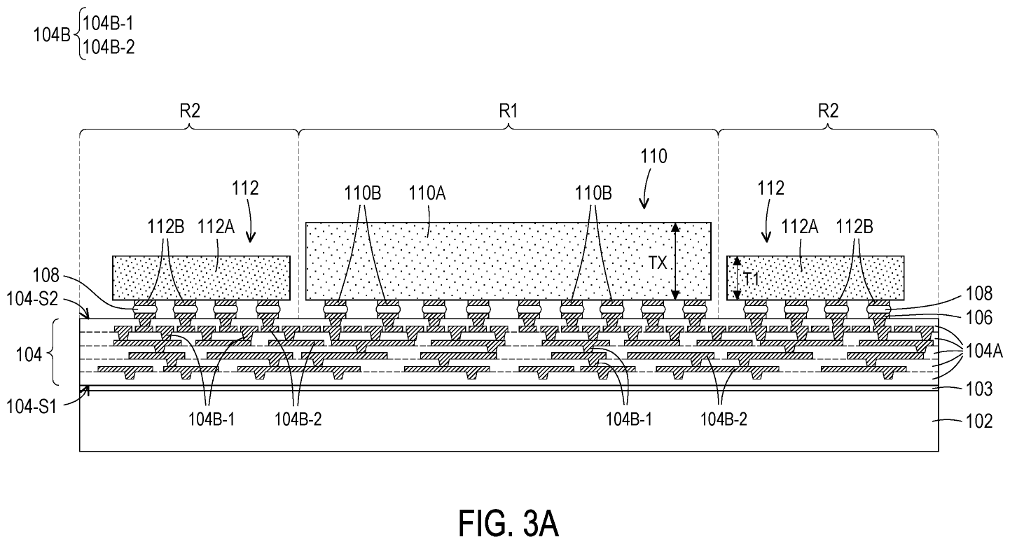

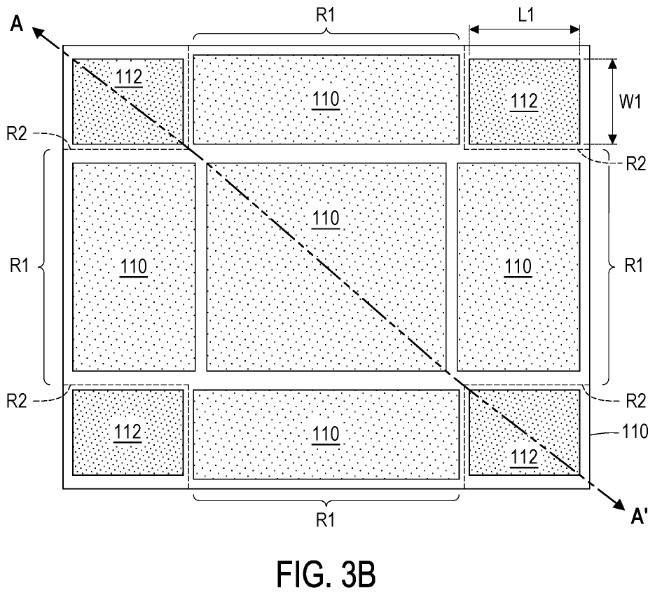

FIG. 3A is a sectional view of the structure shown in FIG. 3B taken along the line A-A′. Referring to FIG. 3A and FIG. 3B, in a subsequent step, a plurality of first semiconductor dies 110 and a plurality of second semiconductor dies 112 are bonded to the interconnection layer 104 through the electrical connectors 108 and the conductive pads 106. As illustrated in FIG. 3A and FIG. 3B, the first semiconductor dies 110 are disposed on a main region R1 of the interconnection layer 104, while the second semiconductor dies 112 are disposed on corner regions R2 of the interconnection layer 104. For example, there are four corner regions R2 (a first corner region, a second corner region, a third corner region and a fourth corner region) that are surrounding the main region R1, and the second semiconductor dies 102 are disposed on each of the four corner regions R2.

In the illustrated embodiment, a width W1 and a length L1 of the second semiconductor dies 112 are smaller than a width and a length of each of the first semiconductor dies 110. However, the disclosure is not limited thereto. For example, in other embodiments, at least one of the width W1 and the length L1 of the second semiconductor dies 112 is smaller than the width and the length of the first semiconductor dies 110, while another one of the width W1 and the length L1 of the second semiconductor dies 112 may be substantially equal to a width or a length of the first semiconductor dies 110. In some embodiments, the width W1 and the length L1 of each of the second semiconductor dies are greater than 2.2 mm for reducing the corner stress of the encapsulant (molding) formed in subsequent steps.

In the exemplary embodiment, a thickness T1 of the second semiconductor dies 112 are smaller than a thickness TX of each of the first semiconductor dies 110 for reducing the corner stress of the encapsulant (molding) formed in subsequent steps. In some embodiments, a ratio (T1:TX) of the thickness T1 to the thickness TX is in a range of 0.05:1 to 0.9:1. For example, the ratio (T1:TX) of the thickness T1 to the thickness TX may be any one of 0.05:1, 0.2:1, 0.3:1, 0.4:1, 0.5:1, 0.6:1, 0.7:1, 0.8:1 or 0.9:1 as long as the thickness T1 of the second semiconductor dies 112 is smaller than the thickness TX of the first semiconductor dies 110.

In the exemplary embodiment, the first semiconductor dies 110 and the second semiconductor dies 112 are individual dies singulated from a wafer. The backsides of the second semiconductor dies 112 may be grinded or partially removed so that is has a reduced thickness (thickness T1) relative to the thickness TX of the first semiconductor dies 110. In some embodiments, the first semiconductor dies 110 contain the same circuitry, such as devices and metallization patterns, or the first semiconductor dies 110 are the same type of dies. In some embodiments, the second semiconductor dies 112 contain the same circuitry, or the second semiconductor dies 112 are the same type of dies. In certain embodiments, the first semiconductor dies 110 and the second semiconductor dies 112 have different circuitry or are different types of dies.

In some embodiments, the first semiconductor dies 110 may be major dies, while the second semiconductor dies 112 are tributary dies. In some embodiments, the major dies are arranged in the main region R1, while tributary dies are arranged in the corner regions R2 and spaced apart from the major dies. In the illustrated embodiment, there are five major dies (first semiconductor dies 110) and four tributary dies (second semiconductor dies 112 with reduced thickness).

In certain embodiments, from the top view shown in FIG. 3B, each of the first semiconductor dies 110 has a surface area larger than that of the second semiconductor dies 112. Also, in some embodiments, the first semiconductor dies 110 and the second semiconductor dies 112 may be of different sizes, including different surface areas and/or different thicknesses. In some embodiments, the first semiconductor dies 110 may be a logic die, including a central processing unit (CPU) die, graphics processing unit (GPU) die, system-on-a-chip (SoC) die, a microcontroller or the like. In some embodiments, the first semiconductor dies 110 is a power management die, such as a power management integrated circuit (PMIC) die. In some embodiments, the first semiconductor dies 110 may be a memory die, including dynamic random access memory (DRAM) die, static random access memory (SRAM) die or a high bandwidth memory (HBM) die. In some embodiments, the first semiconductor dies 110 may be an application-specific integrated circuit (ASIC) die. In some other embodiments, the first semiconductor dies 110 may be a chiplet or the like. In some embodiments, the second semiconductor dies 112 may be non-functional dummy dies, input/output (IO) dies, or integrated passive devices (IPD).

As illustrated in FIG. 3A, the first semiconductor dies 110 include a body 110A and connecting pads 110B formed on an active surface of the body 110A. In certain embodiments, the connecting pads 110B may further include pillar structures for bonding the first semiconductor dies 110 to other structures. Similarly, in some embodiments, the second semiconductor dies 112 include a body 112A and connecting pads 112B formed on an active surface of the body 112A. In other embodiments, the connecting pads 112B may further include pillar structures for bonding the second semiconductor dies 112 to other structures.

In the exemplary embodiment, the first semiconductor dies 110 and the second semiconductor dies 112 are attached to the interconnection layer 104, for example, through flip-chip bonding by way of the electrical connectors 108. Through a reflow process, the electrical connectors 108 are formed between the connecting pads 110B, the connecting pads 112B and the conductive pads 106, and are electrically and physically connecting the first and second semiconductor dies 110, 112 to the interconnection layer 104. In some other embodiments, when the second semiconductor dies 112 are dummy dies, the second semiconductor dies 112 may be joined with dummy electrical connectors 108 that are electrically insulated from the conductive layers 104B of the interconnection layer 104 located underneath. In one embodiment, the electrical connectors 108 are micro-bumps, such as micro-bumps having copper metal pillars. In another embodiment, the electrical connectors 108 are solder bumps, lead-free solder bumps, or micro bumps, such as controlled collapse chip connection (C4) bumps or micro bumps containing copper pillars.

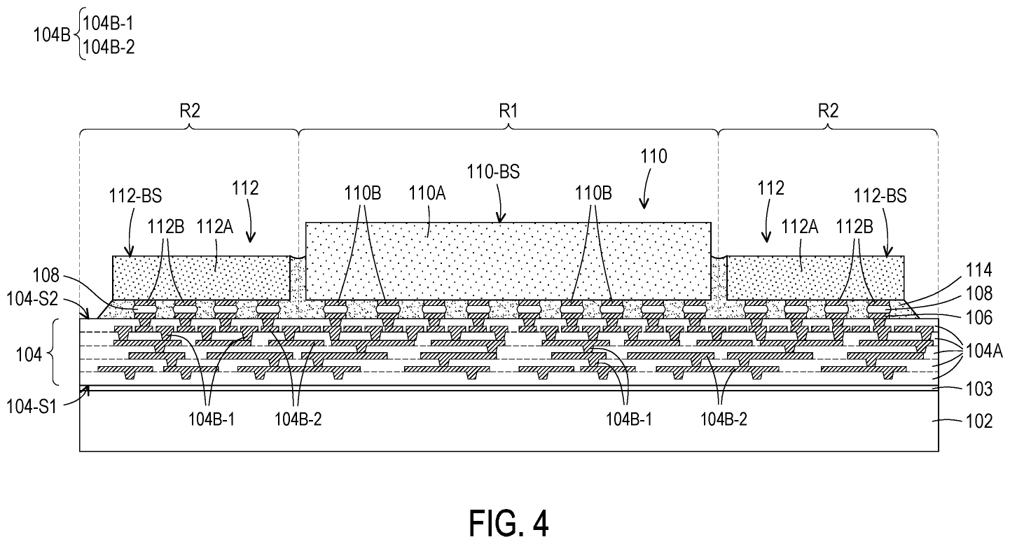

Referring to FIG. 4, in a subsequent step, an underfill structure 114 may be formed to cover the plurality of electrical connectors 108, and to fill up the spaces in between the first semiconductor dies 110, the second semiconductor dies 112 and the interconnection layer 104. In some embodiments, the underfill structure 114 further cover sidewalls of the first semiconductor dies 110 and the second semiconductor dies 112. For example, in the exemplary embodiment, the underfill structure 114 entirely covers sidewalls of the second semiconductor dies 112 that are facing sidewalls of the first semiconductor dies 110, while the underfill structure 114 partially covers the sidewalls of the first semiconductor dies 110.

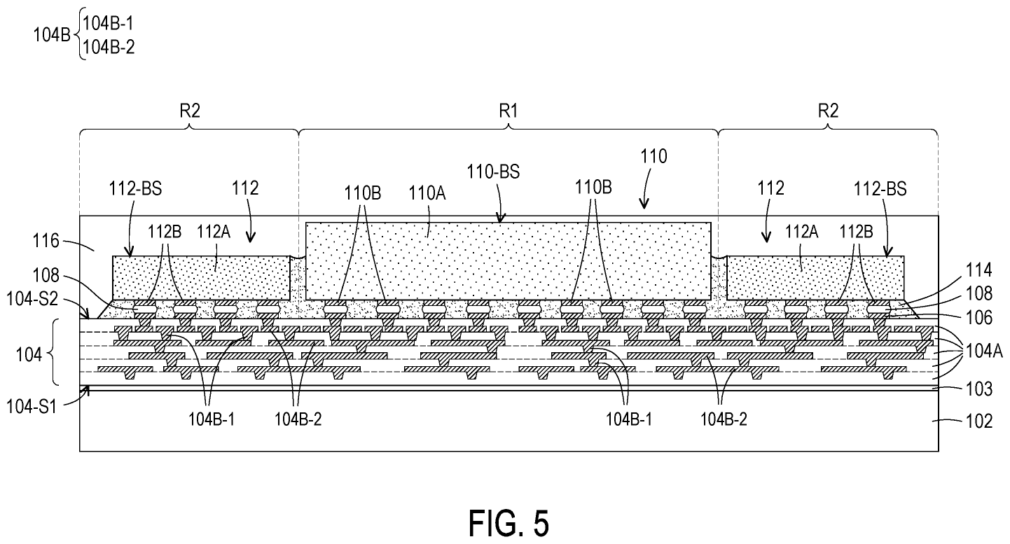

Thereafter, referring to FIG. 5, an insulating encapsulant 116 (or molding compound) may be formed over the interconnection layer 104 to cover the underfill structure 114, and to surround the first and second semiconductor dies 110, 112. In some embodiments, the insulating encapsulant 116 is formed through, for example, a compression molding process or transfer molding. In one embodiment, a curing process is performed to cure the insulating encapsulant 116. In some embodiments, the first and second semiconductor dies 110, 112 and the electrical connectors 108 are encapsulated by the insulating encapsulant 116. In other words, backside surfaces of the first semiconductor dies 110 are not revealed by the insulating encapsulant 116 at this stage.

In some embodiments, a material of the insulating encapsulant 116 includes polymers (such as epoxy resins, phenolic resins, silicon-containing resins, or other suitable resins), dielectric materials having low permittivity (Dk) and low loss tangent (Df) properties, or other suitable materials. In an alternative embodiment, the insulating encapsulant 116 may include an acceptable insulating encapsulation material. In some embodiments, the insulating encapsulant 116 may further include inorganic filler or inorganic compound (e.g. silica, clay, and so on) which can be added therein to optimize coefficient of thermal expansion (CTE) of the insulating encapsulant 116. The disclosure is not limited thereto.

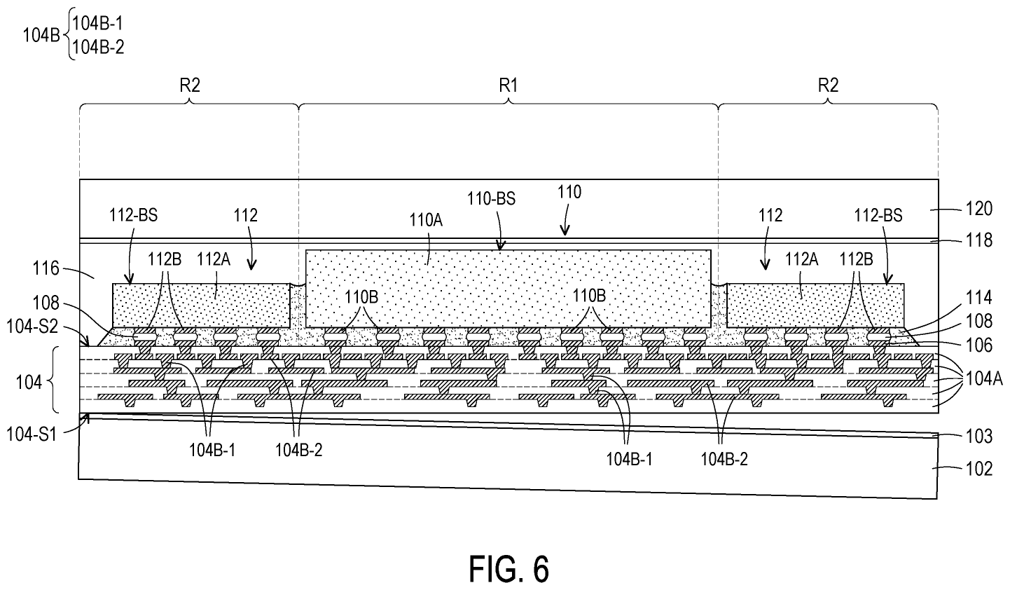

Referring to FIG. 6, after forming the insulating encapsulant 116, a second carrier 120 is bonded onto the insulating encapsulant 116. The second carrier 120 may be a glass carrier or any suitable carrier for carrying a semiconductor wafer or a reconstituted wafer for the manufacturing method of the package structure. In some embodiments, a debond layer 118 is located in between the second carrier 120 and the insulating encapsulant 116. A material of the debond layer 118 may be similar to the debond layer 103 described above, thus its details will not be repeated herein. For example, the material of the debond layer 118 may be any material suitable for bonding and de-bonding the second carrier 120 from the above layer(s) or any wafer(s) disposed thereon.

As further illustrated in FIG. 6, the first carrier 102 is de-bonded, and is separated from the interconnection layer 104. For example, the de-bonding process includes projecting a light such as a laser light or an UV light on the debond layer 103 (e.g., the LTHC release layer) so that the first carrier 102 can be easily removed along with the debond layer 103. In some embodiments, during the de-bonding step, the structure illustrated in FIG. 5 is transferred onto the second carrier 120 having the debond layer 118 coated thereon. In certain embodiments, after the de-bonding process, the second surface 104-S2 of the interconnection layer 104 is revealed.

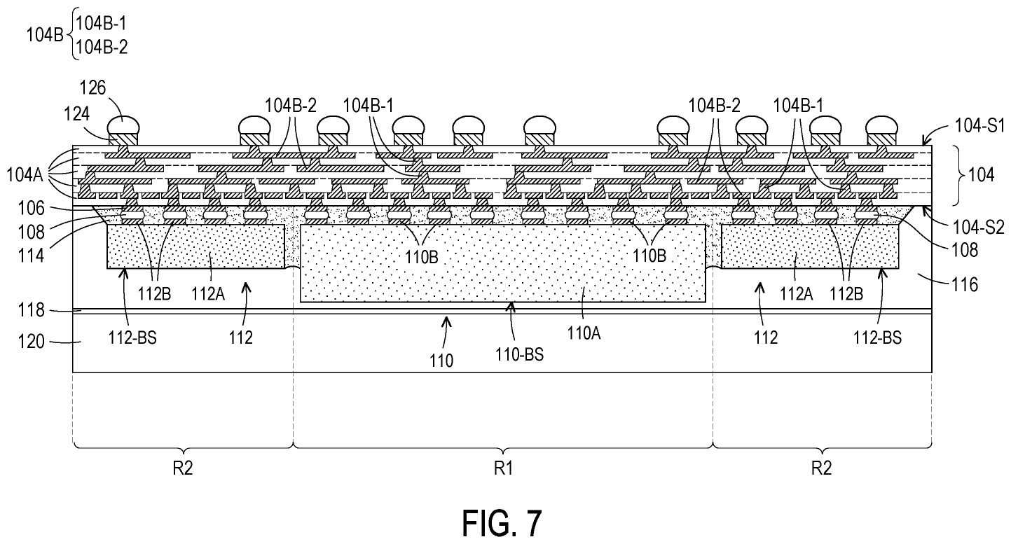

Referring to FIG. 7, in some embodiments, the interconnection layer 104 may be patterned to reveal portions of the conductive layers 104B. Thereafter, a plurality of conductive pads 124 are formed on the second surface 104-S2 of the interconnection layer 104 and are electrically connected to the conductive layers 104B. In some embodiments, the materials of the conductive pads 124 may include copper, nickel, titanium, tungsten, or alloys thereof or the like, and may be formed by an electroplating process, a deposition process, or the like. After forming the conductive pads 124, a plurality of conductive terminals 126 are formed on and electrically connected to the conductive pads 124.

In some embodiments, the conductive terminals 126 include lead-free solder balls, solder balls, ball grid array (BGA) balls, bumps, C4 bumps or micro bumps. In some embodiments, the conductive terminals 126 may include a conductive material such as solder, copper, aluminum, gold, nickel, silver, palladium, tin, or a combination thereof. In some embodiments, the conductive terminals 126 are formed by forming the solder paste on the conductive pads 124 by, for example, evaporation, electroplating, printing or solder transfer and then reflowed into the desired bump shapes. In some embodiments, the conductive terminals 126 are placed on the conductive pads 124 by ball placement or the like. In other embodiments, the conductive terminals 126 are formed by forming solder-free metal pillars (such as a copper pillar) by sputtering, printing, electroless or electro plating or CVD, and then forming a lead-free cap layer by plating on the metal pillars. The conductive terminals 126 may be used to bond to an external device or an additional electrical component. In some embodiments, the conductive terminals 126 are used to bond to a circuit substrate, a semiconductor substrate or a packaging substrate.

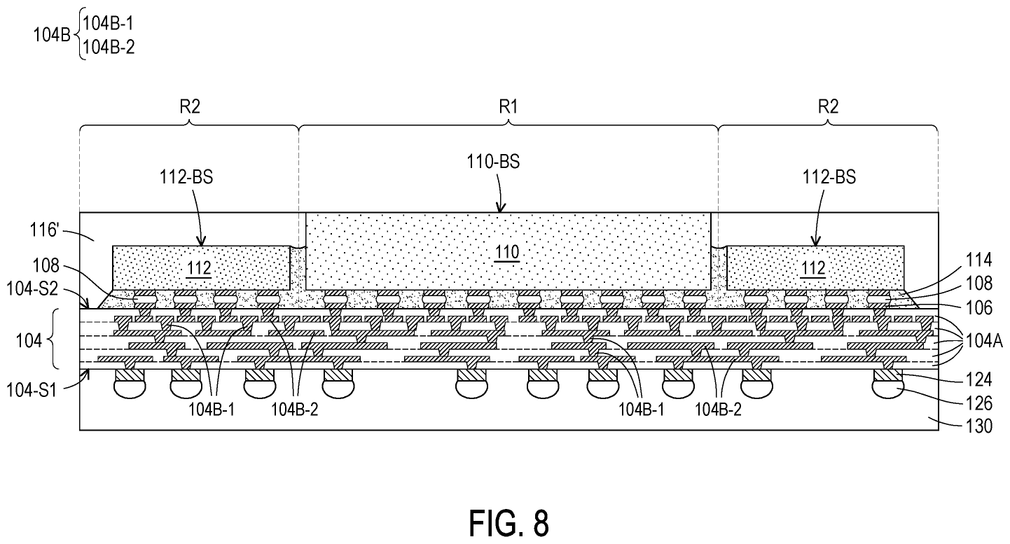

Referring to FIG. 8, in a next step, the structure shown in FIG. 7 is flipped and placed on a tape 130 (e.g. a back grinding (BG) tape). Thereafter, the second carrier 120 is de-bonded, and is separated from the insulating encapsulant 116. For example, the de-bonding process includes projecting a light such as a laser light or an UV light on the debond layer 118 (e.g., the LTHC release layer) so that the second carrier 120 can be easily removed along with the debond layer 118. After removing the second carrier 120, a planarization step is performed through a mechanical grinding process and/or a chemical mechanical polishing (CMP) process to remove portions of the insulating encapsulant 116 until backside surfaces 110-BS of the first semiconductor dies 110 are revealed.

In the illustrated embodiment, a portion of the insulating encapsulant 116 is polished and removed to form an insulating encapsulant 116′. In some embodiments, after the mechanical grinding or chemical mechanical polishing (CMP) steps, a cleaning step may be optionally performed. For example, the cleaning step is preformed to clean and remove the residue generated from the planarization step. In certain embodiments, after the cleaning step, a surface of the insulating encapsulant 116′ is coplanar and levelled with the backside surface 110-BS of the first semiconductor dies 110. In other words, the backside surfaces 110-BS of the first semiconductor dies 110 are revealed by the insulating encapsulant 116′, while backside surfaces 112-BS of the second semiconductor dies 112 are covered by the insulating encapsulant 116′.

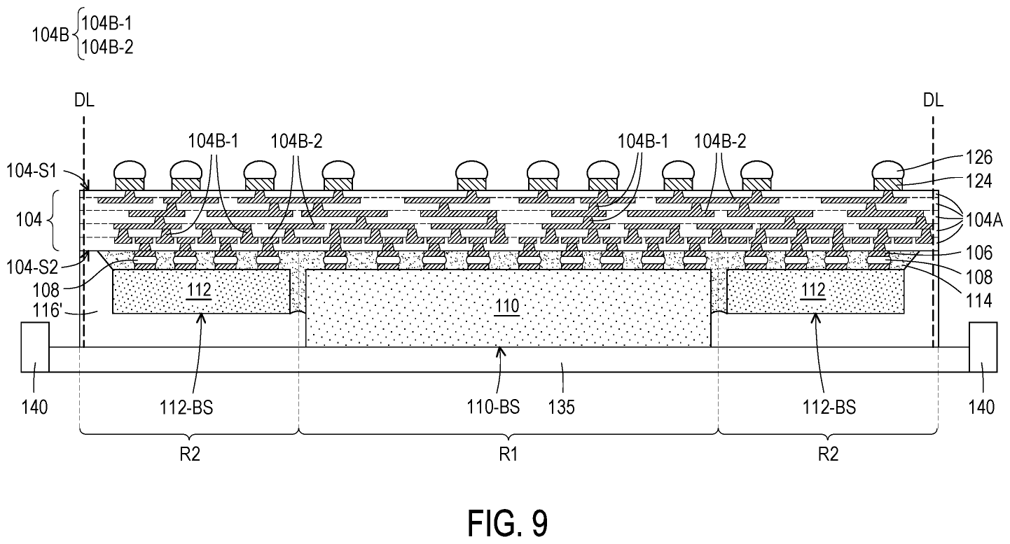

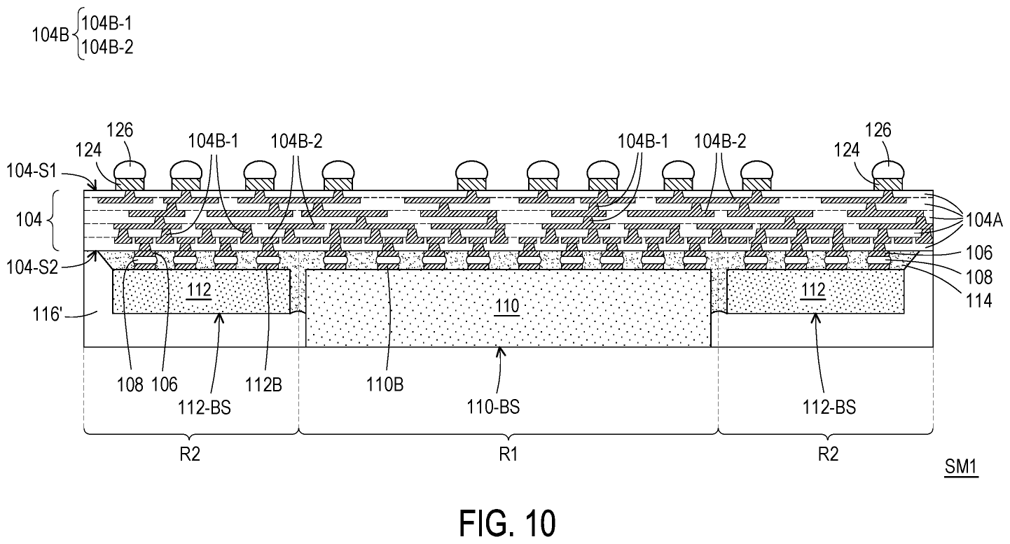

Referring to FIG. 9, in a subsequent step, the structure shown in FIG. 8 is removed from the tape 130, and further attached to another tape 135 (e.g., a dicing tape) supported by a frame 140. Thereafter, the structure is diced or singulated along the dicing lanes DL to form a plurality of semiconductor packages SM1 shown in FIG. 10. For example, the dicing process is performed by cutting through the interconnection layer 104 and the insulating encapsulant 116′ to separate individual semiconductor packages SM1 from one another.

As illustrated in FIG. 10, in the semiconductor package SM1, the plurality of second semiconductor dies 112 with the reduced thickness are embedded in four corners of the insulating encapsulant 116′, or are located on corner regions R2 of the interconnection layer 104. As such, due to the reduced thickness of the second semiconductor dies 112 and with the insulating encapsulant 116′ covering up the backside surfaces 112-BS of the second semiconductor dies 112, the molding stress at the corner of the semiconductor package SM1 can be reduced. In other words, with an increased occupied area of the insulating encapsulant 116′ at the corner of the semiconductor package SM1, when bonding the semiconductor package SM1 onto a substrate, the substrate contraction force can be counteracted, and a molding delamination risk at the corners can be reduced.

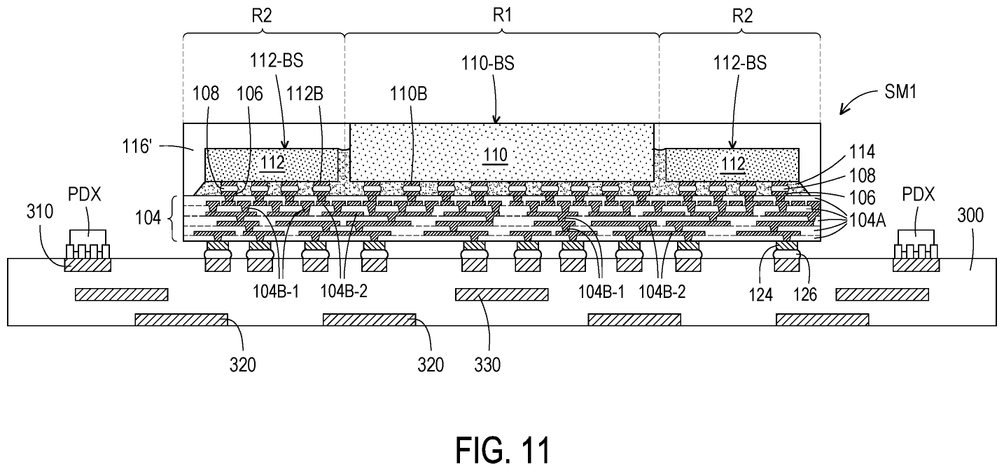

Referring to FIG. 11, in the exemplary embodiment, the semiconductor package SM1 obtained in FIG. 10 is mounted or attached onto a circuit substrate 300 through the conductive terminals 126. In some embodiments, the circuit substrate 300 includes contact pads 310, contact pads 320, metallization layers 330, and vias (not shown). In some embodiments, the contact pads 310 and the contact pads 320 are respectively distributed on two opposite sides of the circuit substrate 300, and are exposed for electrically connecting with later-formed elements/features. In some embodiments, the metallization layers 330 and the vias are embedded in the circuit substrate 300 and together provide routing function for the circuit substrate 300, wherein the metallization layers 330 and the vias are electrically connected to the contact pads 310 and the contact pads 320. In other words, at least some of the contact pads 310 are electrically connected to some of the contact pads 320 through the metallization layers 330 and the vias. In some embodiments, the contact pads 310 and the contact pads 320 may include metal pads or metal alloy pads. In some embodiments, the materials of the metallization layers 330 and the vias may be substantially the same or similar to the material of the contact pads 310 and the contact pads 320.

Furthermore, in some embodiments, the semiconductor package SM1 is bonded to the circuit substrate 300 through physically connecting the conductive terminals 126 and the contact pads 310 to form a stacked structure. In certain embodiments, the semiconductor package SM1 is electrically connected to the circuit substrate 300. In some embodiments, the circuit substrate 300 is such as an organic flexible substrate or a printed circuit board. In such embodiments, the conductive terminals 126 are, for example, chip connectors. In some embodiments, the semiconductor package SM1 is bonded to the circuit substrate 300 through physically connecting the conductive terminals 126 and the contact pads 310 of the circuit substrate 300 by a chip on wafer on substrate (CoWoS) packaging processes. In addition, as illustrated in FIG. 11, passive devices PDX (integrated passive device or surface mount devices) may be mounted on the circuit substrate 300. For example, the passive devices PDX may be mounted on the contact pads 310 of the circuit substrate 300 through a soldering process. The disclosure is not limited thereto. In certain embodiments, the passive devices PDX may be mounted on the circuit substrate 300 to surround the semiconductor package SM1.

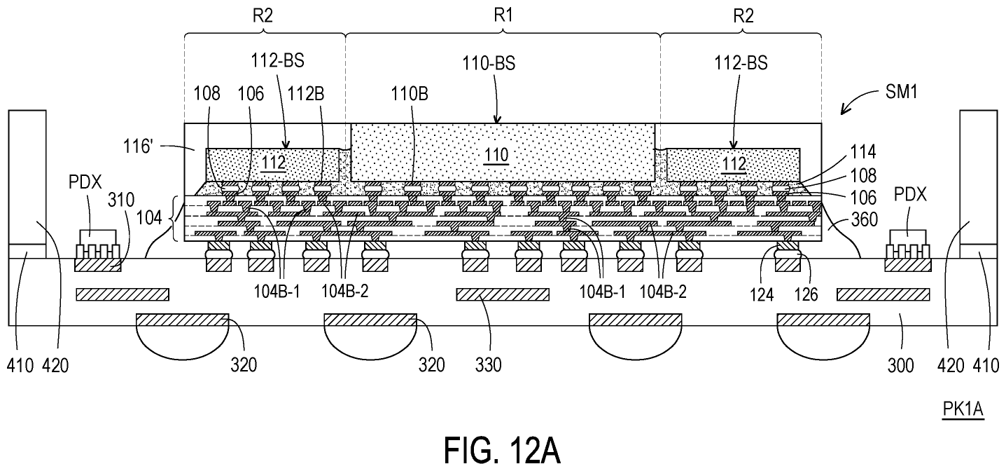

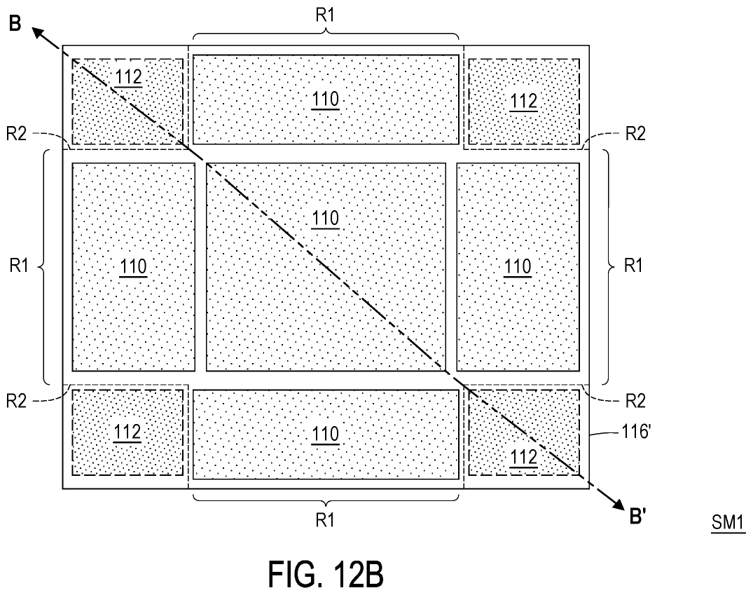

FIG. 12B illustrates a top view of the semiconductor package SM1, whereby FIG. 12A illustrates a sectional view of an obtained package structure PK1A including the semiconductor package SM1 of FIG. 12B taken along the lines B-B′. Referring to FIG. 12A and FIG. 12B, in a subsequent step, an underfill structure 360 is formed to fill up the spaces in between the circuit substrate 300 and the semiconductor package SM1. In certain embodiments, the underfill structure 360 fills up the spaces in between adjacent conductive terminals 126 and covers the conductive terminals 126. For example, the underfill structure 360 surrounds the plurality of conductive terminals 126. In some embodiments, the underfill structure 360 further covers the conductive pads 124. In some embodiments, the passive devices PDX is exposed by the underfill structure 360, and kept a distance apart from the underfill structure 360. In other words, the underfill structure 360 does not cover the passive devices PDX.

As further illustrated in FIG. 12A, a plurality of conductive balls 340 are respectively formed on the substrate 300. For example, the conductive balls 340 are connected to the contact pads 320 of the circuit substrate 300. In other words, the conductive balls 340 are electrically connected to the circuit substrate 300 through the contact pads 320. Through the contact pads 310 and the contact pads 320, some of the conductive balls 340 are electrically connected to the semiconductor package SM1 (e.g. the first and semiconductor dies 110 and 112 included therein). In some embodiments, the conductive balls 340 are, for example, solder balls or BGA balls.

Furthermore, in a subsequent step, a stiffener ring 420 is attached to the circuit substrate 300 through an adhesive 410. For example, the stiffener ring 420 is disposed on the circuit substrate 300 and laterally surrounds the semiconductor package SM1. In some embodiments, the stiffener ring 420 is made of a metallic material. The stiffener ring 420 serve to reduce the warpage on the circuit substrate 300 caused by bonding of the semiconductor package SM1 thereto. After attaching the stiffener ring 420, the package structure PK1A in accordance with some embodiments of the present disclosure can be accomplished.

In the package structure PK1A, the second semiconductor dies 112 with the reduced thickness are located at corners of the semiconductor package SM1. For example, the second semiconductor dies 112 are disposed on a first corner region R2 (top right R2 in FIG. 12B), on a second corner region R2 (top left R2 in FIG. 12B), a third corner region R2 (bottom left R2 in FIG. 12B), and a fourth corner region R2 (bottom right R2 in FIG. 12B) on the interconnection layer 104. Therefore, when bonding the semiconductor package SM1 onto the circuit substrate 300, the substrate contraction force can be counteracted, and a molding delamination risk at the corners of the insulating encapsulant 116′ can be reduced. Furthermore, in some embodiments, for heat dissipation of the first semiconductor dies 110 in the semiconductor package SM1, the backside surface 110-BS of the first semiconductor dies 110 are revealed from the insulating encapsulant 116′. In certain embodiments, a thermal insulating material (TIM) or a heat sink (not shown) may be further attached to the backside surface 110-BS of the first semiconductor dies 110. Overall, a package structure PK1A with improved reliability and improved heat dissipation can be achieved.

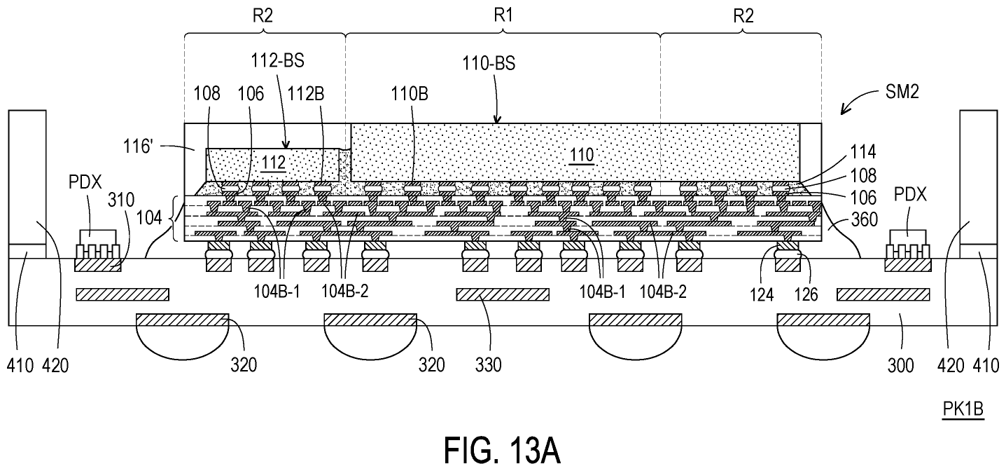

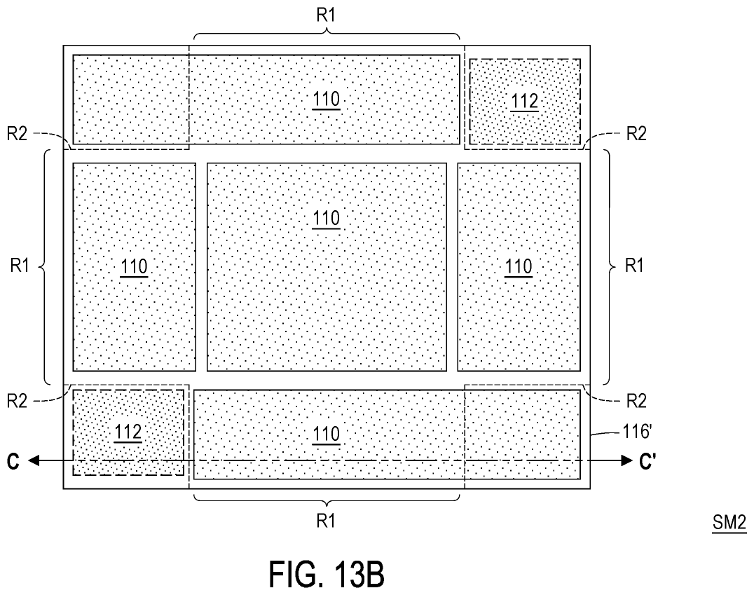

FIG. 13A and FIG. 13B are schematic sectional and top views of a package structure according to some other exemplary embodiments of the present disclosure. The package structure PK1B illustrated in FIG. 13A and FIG. 13B are similar to the package structure PK1A illustrated in FIG. 12A and FIG. 12B. Therefore, the same reference numerals are used to refer to the same or like parts, and its detailed description will be omitted herein. The difference between the embodiments is that the semiconductor package SM1 illustrated in FIG. 12A and FIG. 12B are replaced with the semiconductor package SM2 illustrated in FIG. 13A and FIG. 13B.

FIG. 13B illustrates a top view of the semiconductor package SM2, whereby FIG. 13A illustrates a sectional view of an obtained package structure PK1B including the semiconductor package SM2 of FIG. 13B taken along the lines C-C′. Referring to FIG. 13A and FIG. 13B, in the package structure PK1B, the second semiconductor dies 112 with the reduced thickness are located at corners of the semiconductor package SM2. For example, the second semiconductor dies 112 are disposed on a first corner region R1 (top right R2 in FIG. 13B) and a third corner region R1 (bottom left R2 in FIG. 13B) on the interconnection layer 104. As such, when bonding the semiconductor package SM2 onto the circuit substrate 300, the substrate contraction force can be counteracted, and a molding delamination risk at the corners of the insulating encapsulant 116′ can be reduced.

Furthermore, in some embodiments, a portion of the first semiconductor dies 110 extends from the main region R1 towards the second corner region R2 (top left R2 in FIG. 13B) and the fourth corner region (bottom right R2 in FIG. 13B) on the interconnection layer 104. In certain embodiments, for heat dissipation of the first semiconductor dies 110 in the semiconductor package SM1, the backside surface 110-BS of the first semiconductor dies 110 are revealed from the insulating encapsulant 116′. For example, a thermal insulating material (TIM) or a heat sink (not shown) may be further attached to the backside surface 110-BS of the first semiconductor dies 110. Overall, a package structure PK1B with improved reliability and improved heat dissipation can be achieved.

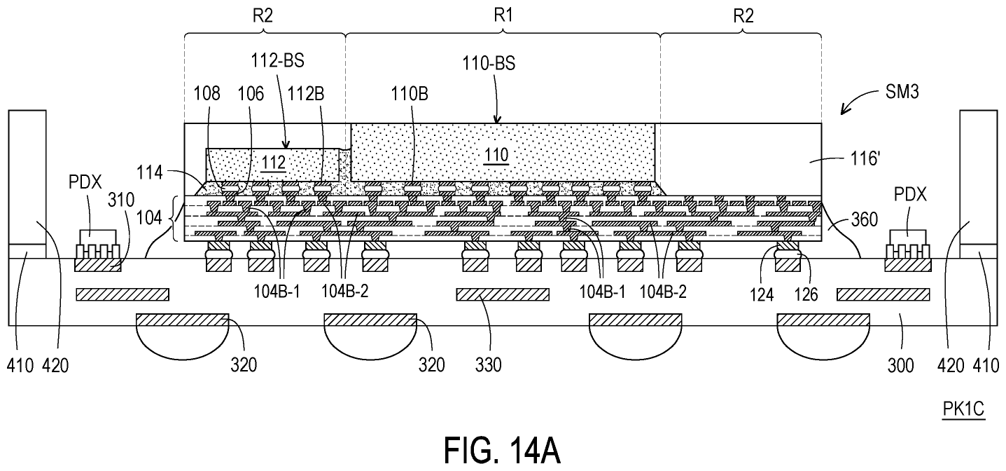

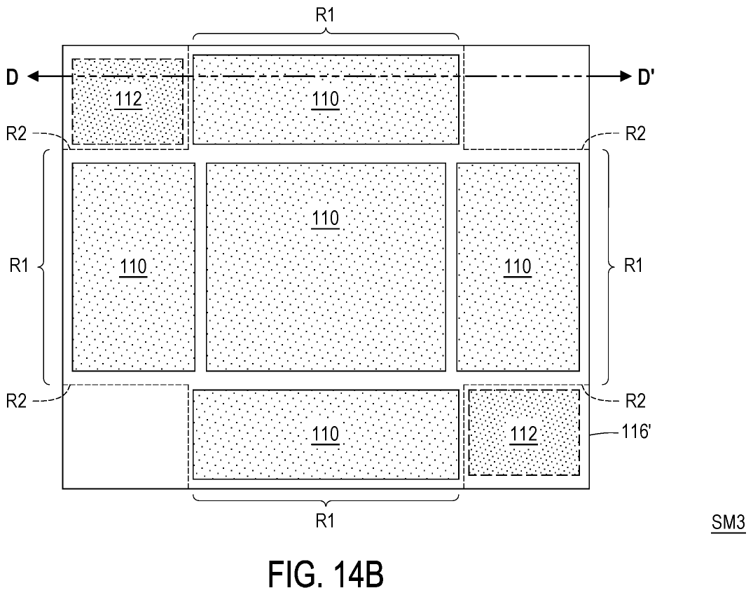

FIG. 14A and FIG. 14B are schematic sectional and top views of a package structure according to some other exemplary embodiments of the present disclosure. The package structure PK1C illustrated in FIG. 14A and FIG. 14B are similar to the package structure PK1A illustrated in FIG. 12A and FIG. 12B. Therefore, the same reference numerals are used to refer to the same or like parts, and its detailed description will be omitted herein. The difference between the embodiments is that the semiconductor package SM1 illustrated in FIG. 12A and FIG. 12B are replaced with the semiconductor package SM3 illustrated in FIG. 14A and FIG. 14B.

FIG. 14B illustrates a top view of the semiconductor package SM3, whereby FIG. 14A illustrates a sectional view of an obtained package structure PK1C including the semiconductor package SM3 of FIG. 14B taken along the lines D-D′. Referring to FIG. 14A and FIG. 14B, in the package structure PK1C, the second semiconductor dies 112 with the reduced thickness are located at corners of the semiconductor package SM2. For example, the second semiconductor dies 112 are disposed on a first corner region R1 (top left R2 in FIG. 14B) and a third corner region R1 (bottom right R2 in FIG. 14B) on the interconnection layer 104. Furthermore, no dies are located on the second corner region R1 (top right R2 in FIG. 14B) and the fourth corner region (bottom left R2 in FIG. 14B), and wherein the insulating encapsulant 116′ covers up the second corner region R2 and the fourth corner region R2.

As such, when bonding the semiconductor package SM3 onto the circuit substrate 300, the substrate contraction force can be counteracted, and a molding delamination risk at the corners of the insulating encapsulant 116′ can be reduced. Furthermore, in some embodiments, for heat dissipation of the first semiconductor dies 110 in the semiconductor package SM3, the backside surface 110-BS of the first semiconductor dies 110 are revealed from the insulating encapsulant 116′. In certain embodiments, a thermal insulating material (TIM) or a heat sink (not shown) may be further attached to the backside surface 110-BS of the first semiconductor dies 110. Overall, a package structure PK1C with improved reliability and improved heat dissipation can be achieved.

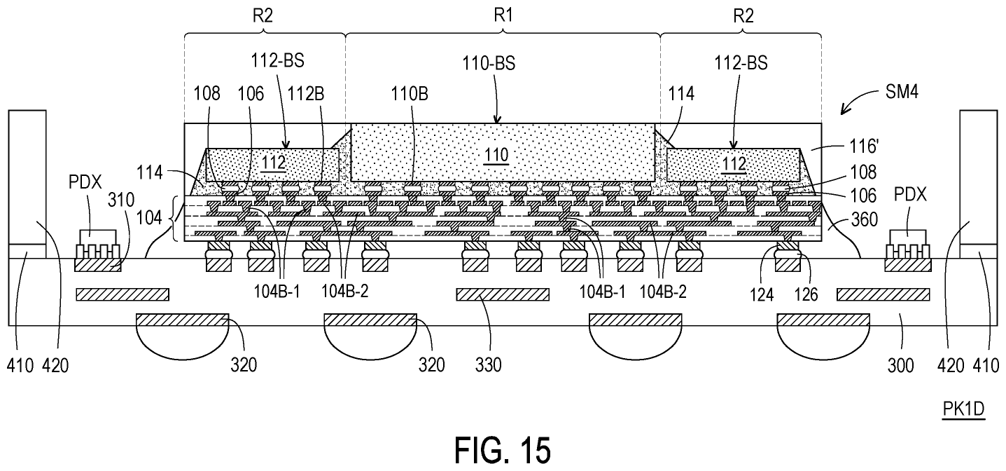

FIG. 15 is a schematic sectional view of a package structure according to some other exemplary embodiments of the present disclosure. The package structure PK1D illustrated in FIG. 15 is similar to the package structure PK1A illustrated in FIG. 12A and FIG. 12B. Therefore, the same reference numerals are used to refer to the same or like parts, and its detailed description will be omitted herein. The difference between the embodiments is that the semiconductor package SM1 illustrated in FIG. 12A and FIG. 12B are replaced with the semiconductor package SM4 illustrated in FIG. 15.

Referring to FIG. 15, in the semiconductor package SM4, the underfill structure 114 entirely covers sidewalls of the second semiconductor dies 112 that are facing sidewalls of the first semiconductor dies 110, while the underfill structure 114 partially covers the sidewalls of the first semiconductor dies 110. Furthermore, in some embodiments, the underfill structure 114 further covers and contact the backside surfaces 112-BS of the plurality of second semiconductor dies 112. For example, the underfill structure 114 partially covers and contacts the backside surfaces 112-BS while revealing portions of the backside surface 112-BS.

In the package structure PK1D, the second semiconductor dies 112 with the reduced thickness are located at corners of the semiconductor package SM4. In other words, the semiconductor package SM4 of FIG. 15 has a top view that is similar to the semiconductor package SM1 illustrated in FIG. 12B. In the exemplary embodiment, the second semiconductor dies 112 are disposed on a first corner region R2, on a second corner region R2, a third corner region R2, and a fourth corner region R2 on the interconnection layer 104. Therefore, when bonding the semiconductor package SM4 onto the circuit substrate 300, the substrate contraction force can be counteracted, and a molding delamination risk at the corners of the insulating encapsulant 116′ can be reduced. Furthermore, in some embodiments, for heat dissipation of the first semiconductor dies 110 in the semiconductor package SM4, the backside surface 110-BS of the first semiconductor dies 110 are revealed from the insulating encapsulant 116′. In certain embodiments, a thermal insulating material (TIM) or a heat sink (not shown) may be further attached to the backside surface 110-BS of the first semiconductor dies 110. Overall, a package structure PK1D with improved reliability and improved heat dissipation can be achieved.

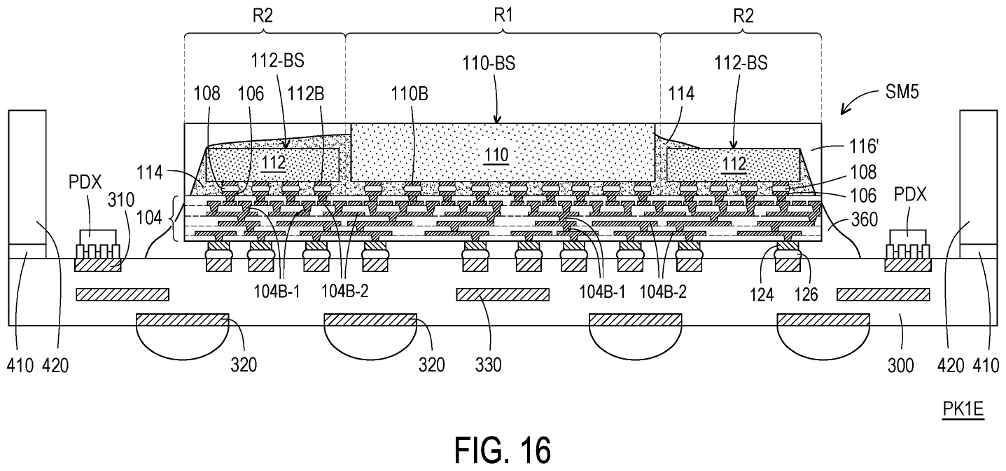

FIG. 16 is a schematic sectional view of a package structure according to some other exemplary embodiments of the present disclosure. The package structure PK1E illustrated in FIG. 16 is similar to the package structure PK1A illustrated in FIG. 12A and FIG. 12B. Therefore, the same reference numerals are used to refer to the same or like parts, and its detailed description will be omitted herein. The difference between the embodiments is that the semiconductor package SM1 illustrated in FIG. 12A and FIG. 12B are replaced with the semiconductor package SM5 illustrated in FIG. 16.

Referring to FIG. 16, in the semiconductor package SM5, the underfill structure 114 entirely covers sidewalls of the second semiconductor dies 112 that are facing sidewalls of the first semiconductor dies 110, while the underfill structure 114 partially covers the sidewalls of the first semiconductor dies 110. Furthermore, in some embodiments, the underfill structure 114 further covers and contact the backside surfaces 112-BS of the plurality of second semiconductor dies 112. For example, the underfill structure 114 is fully covering and contacting the backside surfaces 112-BS of one of the second semiconductor dies 112 (which may be a dummy die), and may be partially covering and contacting the backside surfaces 112-BS of other second semiconductor dies 112 (which may be dummy dies, IO dies or IPD).

In the package structure PK1E, the second semiconductor dies 112 with the reduced thickness are located at corners of the semiconductor package SM5. In other words, the semiconductor package SM5 of FIG. 16 has a top view that is similar to the semiconductor package SM1 illustrated in FIG. 12B. In the exemplary embodiment, the second semiconductor dies 112 are disposed on a first corner region R2, on a second corner region R2, a third corner region R2, and a fourth corner region R2 on the interconnection layer 104. Therefore, when bonding the semiconductor package SM5 onto the circuit substrate 300, the substrate contraction force can be counteracted, and a molding delamination risk at the corners of the insulating encapsulant 116′ can be reduced. Furthermore, in some embodiments, for heat dissipation of the first semiconductor dies 110 in the semiconductor package SM5, the backside surface 110-BS of the first semiconductor dies 110 are revealed from the insulating encapsulant 116′. In certain embodiments, a thermal insulating material (TIM) or a heat sink (not shown) may be further attached to the backside surface 110-BS of the first semiconductor dies 110. Overall, a package structure PK1E with improved reliability and improved heat dissipation can be achieved.

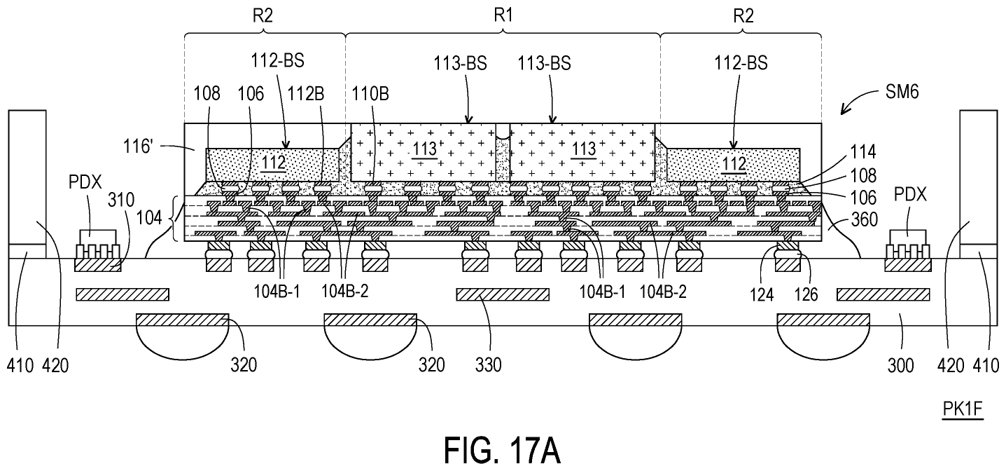

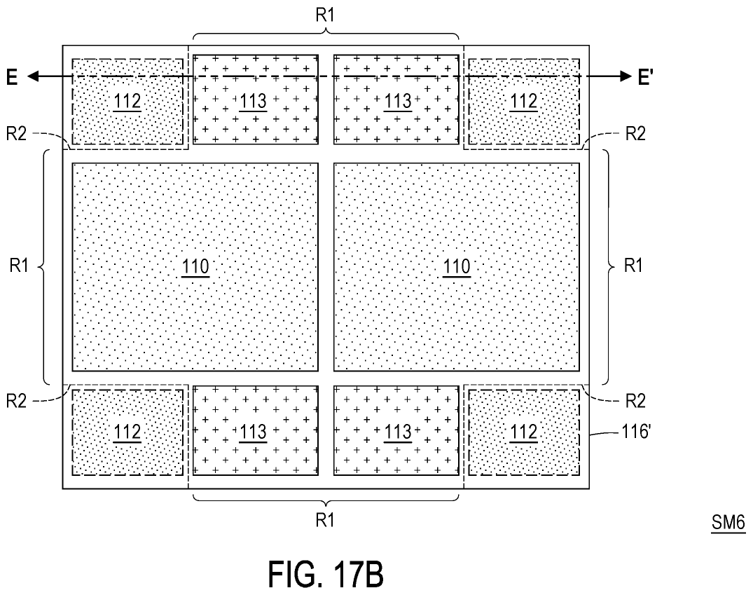

FIG. 17A and FIG. 17B are schematic sectional and top views of a package structure according to some other exemplary embodiments of the present disclosure. The package structure PK1F illustrated in FIG. 17A and FIG. 17B are similar to the package structure PK1A illustrated in FIG. 12A and FIG. 12B. Therefore, the same reference numerals are used to refer to the same or like parts, and its detailed description will be omitted herein. The difference between the embodiments is that the semiconductor package SM1 illustrated in FIG. 12A and FIG. 12B are replaced with the semiconductor package SM6 illustrated in FIG. 17A and FIG. 17B.

FIG. 17B illustrates a top view of the semiconductor package SM6, whereby FIG. 17A illustrates a sectional view of an obtained package structure PK1F including the semiconductor package SM6 of FIG. 17B taken along the lines E-E′. Referring to FIG. 17A and FIG. 17B, in the package structure PK1F, a plurality of third semiconductor dies 113 are further disposed aside the first semiconductor dies 110 on the main region R1 of the interconnection layer 104, and are embedded in the insulating encapsulant 116′. In the exemplary embodiment, a width and a length of the third semiconductor dies 113 are equal to the width W1 and the length L1 of the second semiconductor dies 112, and wherein backside surfaces 113-BS of the third semiconductor dies 113 are revealed by the insulating encapsulant 116′. In some embodiments, a thickness of the third semiconductor dies 113 is equal to the thickness TX of the first semiconductor dies 110. Furthermore, the third semiconductor dies 113 and the second semiconductor dies 112 are the same type of dies. For example, the third semiconductor dies 113 may be non-functional dummy dies, input/output (IO) dies, or integrated passive devices (IPD).

In the package structure PK1F, the second semiconductor dies 112 with the reduced thickness are located at corners of the semiconductor package SM6. For example, the second semiconductor dies 112 are disposed on a first corner region R2 (top right R2 in FIG. 17B), on a second corner region R2 (top left R2 in FIG. 17B), a third corner region R2 (bottom left R2 in FIG. 17B), and a fourth corner region R2 (bottom right R2 in FIG. 17B) on the interconnection layer 104. Therefore, when bonding the semiconductor package SM6 onto the circuit substrate 300, the substrate contraction force can be counteracted, and a molding delamination risk at the corners of the insulating encapsulant 116′ can be reduced. Furthermore, in some embodiments, for heat dissipation of the first semiconductor dies 110 and the third semiconductor dies 113 in the semiconductor package SM6, the backside surface 110-BS of the first semiconductor dies 110 and the backside surface 113-BS of the third semiconductor dies 113 are revealed from the insulating encapsulant 116′. In certain embodiments, a thermal insulating material (TIM) or a heat sink (not shown) may be further attached to the backside surface 110-BS of the first semiconductor dies 110 and the backside surface 113-BS of the third semiconductor dies 113. Overall, a package structure PK1F with improved reliability and improved heat dissipation can be achieved.

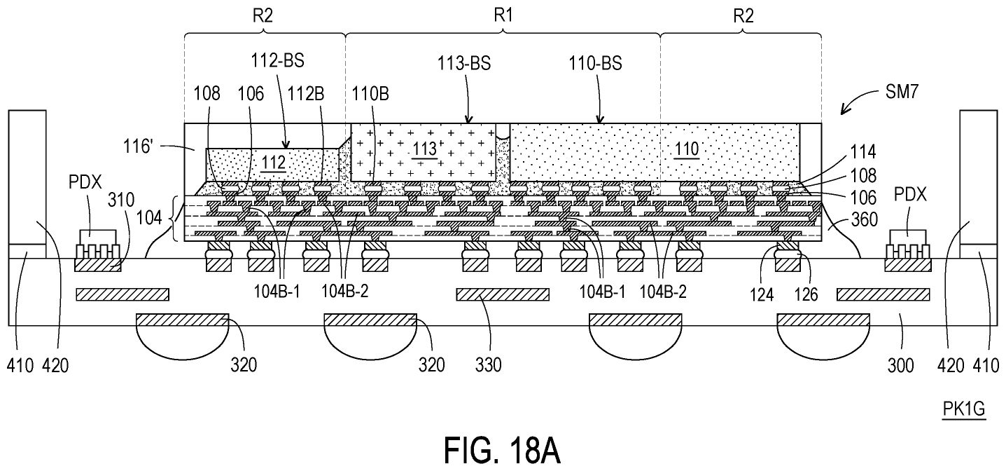

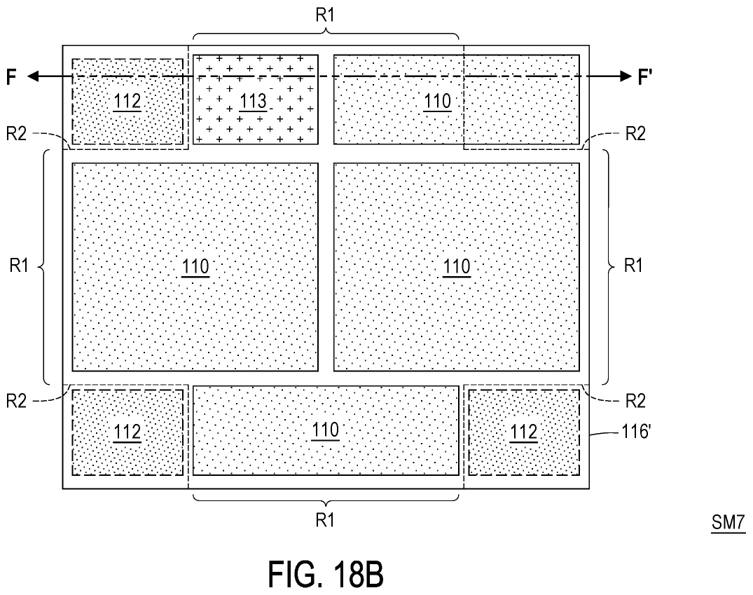

FIG. 18A and FIG. 18B are schematic sectional and top views of a package structure according to some other exemplary embodiments of the present disclosure. The package structure PK1G illustrated in FIG. 18A and FIG. 18B are similar to the package structure PK1F illustrated in FIG. 17A and FIG. 17B. Therefore, the same reference numerals are used to refer to the same or like parts, and its detailed description will be omitted herein. The difference between the embodiments is that the semiconductor package SM6 illustrated in FIG. 17A and FIG. 17B are replaced with the semiconductor package SM7 illustrated in FIG. 18A and FIG. 18B.

FIG. 18B illustrates a top view of the semiconductor package SM7, whereby FIG. 18A illustrates a sectional view of an obtained package structure PK1G including the semiconductor package SM7 of FIG. 18B taken along the lines F-F′. Referring to FIG. 18A and FIG. 18B, the semiconductor package SM7 includes a plurality of first semiconductor dies 110, a plurality of second semiconductor dies 112 and a third semiconductor die 113. In the exemplary embodiment, the second semiconductor dies 112 are disposed on a second corner region R2 (top left R2 in FIG. 18B), a third corner region R2 (bottom left R2 in FIG. 18B), and a fourth corner region R2 (bottom right R2 in FIG. 18B) on the interconnection layer 104. Furthermore, one of the first semiconductor die 110 extends from the main region R1 towards a first corner region R2 (top right R2 in FIG. 18B) on the interconnection layer 104. In certain embodiments, the third semiconductor die 113 is disposed in the main region R1 on the interconnection layer 104, and is located aside the first semiconductor die 110 and the second semiconductor die 112.

In the package structure PK1G, the second semiconductor dies 112 with the reduced thickness are located at corners of the semiconductor package SM6. Therefore, when bonding the semiconductor package SM7 onto the circuit substrate 300, the substrate contraction force can be counteracted, and a molding delamination risk at the corners of the insulating encapsulant 116′ can be reduced. Furthermore, in some embodiments, for heat dissipation of the first semiconductor dies 110 and the third semiconductor dies 113 in the semiconductor package SM7, the backside surface 110-BS of the first semiconductor dies 110 and the backside surface 113-BS of the third semiconductor dies 113 are revealed from the insulating encapsulant 116′. In certain embodiments, a thermal insulating material (TIM) or a heat sink (not shown) may be further attached to the backside surface 110-BS of the first semiconductor dies 110 and the backside surface 113-BS of the third semiconductor dies 113. Overall, a package structure PK1G with improved reliability and improved heat dissipation can be achieved.

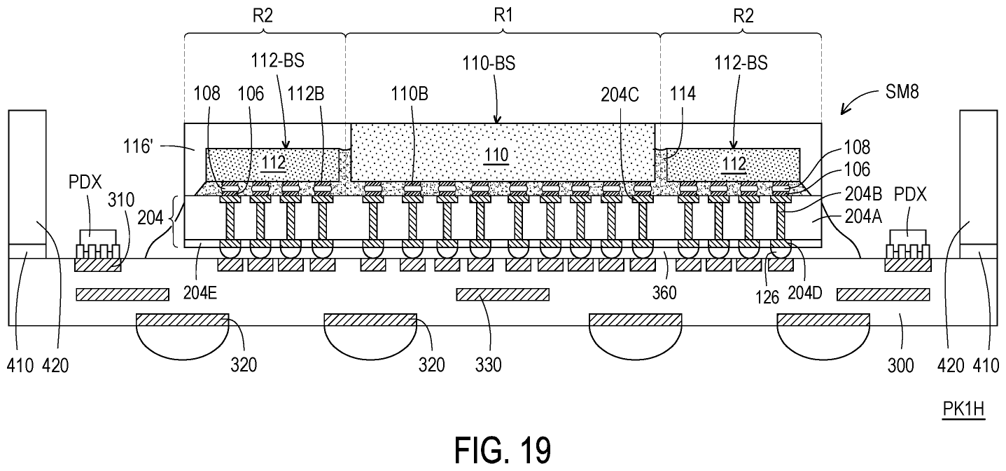

FIG. 19 is a schematic sectional view of a package structure according to some other exemplary embodiments of the present disclosure. The package structure PK1H illustrated in FIG. 19 is similar to the package structure PK1A illustrated in FIG. 12A and FIG. 12B. Therefore, the same reference numerals are used to refer to the same or like parts, and its detailed description will be omitted herein. The difference between the embodiments is that the semiconductor package SM1 illustrated in FIG. 12A and FIG. 12B are replaced with the semiconductor package SM8 illustrated in FIG. 19.

In the semiconductor packages of the previous embodiments, the interconnection layer 104 is a redistribution layer including alternatingly stacked conductive layers 104B and dielectric layers 104A. However, the disclosure is not limited thereto. Referring to FIG. 19, in some other embodiments, the interconnection layer 204 is an interposer structure. For example, in the illustrated embodiment, the interconnection layer 204 (interposer structure) includes a core portion 204A, and a plurality of through vias 204B and conductive pads 204C formed therein. In some embodiments, the core portion 204A is a substrate such as a bulk semiconductor substrate, silicon on insulator (SOI) substrate or a multi-layered semiconductor material substrate. The semiconductor material of the substrate (core portion 204A) may be silicon, germanium, silicon germanium, silicon carbide, gallium arsenic, gallium phosphide, indium phosphide, indium arsenide, indium antimonide, GaAsP, AlInAs, AlGaAs, GaInAs, GaInP, GaInAsP, or combinations thereof. In some embodiments, the core portion 102 is doped or undoped.

In some embodiments, the conductive pads 204C are formed on a surface of the core portion 204A, and are electrically connected to the conductive pads 106. In some embodiments, through vias 204B are formed in the core portion 204A and connected with the conductive pads 204C. In some embodiments, the through vias 204B are through-substrate vias. In some embodiments, the through vias 204B are through-silicon vias when the core portion 204A is a silicon substrate. In some embodiments, the through vias 204B may be formed by forming holes or recesses in the core portion 204A and then filling the recesses with a conductive material. In some embodiments, the recesses may be formed by, for example, etching, milling, laser drilling or the like. In some embodiments, the conductive material may be formed by an electro-chemical plating process, chemical vapor deposition (CVD), atomic layer deposition (ALD) or physical vapor deposition (PVD), and the conductive material may include copper, tungsten, aluminum, silver, gold or a combination thereof. In some embodiments, the conductive pads 204C connected with the through vias 204B may be formed as conductive parts of the redistribution layer(s) formed on the interconnection layer 204. In some embodiments, the conductive pads 204C include under bump metallurgies (UBMs). In certain embodiments, the interconnection layer 204 (interposer structure) may further include active or passive devices, such as transistors, capacitors, resistors, or diodes passive devices formed in the core portion 204A.

As further illustrated in FIG. 19, a redistribution structure including metallization patterns 204D and at least one dielectric layer 204E are formed on the core portion 204A. In some embodiments, the metallization patterns 204D may comprise pads, vias and/or trace lines to interconnect the through vias 204B and to further connect the through vias 204B to one or more external devices. Although one layer of dielectric layer 204E, and one layer of the metallization patterns 204D is shown in FIG. 19, it should be noted that the number of layers of the dielectric layer 204E and the metallization patterns 204D is not limited thereto, and could be adjusted based on requirement.

In some embodiments, the material of the dielectric layer 204E comprises silicon oxide, silicon nitride, silicon carbide, silicon oxynitride, or low-K dielectric materials (such as phosphosilicate glass materials, fluorosilicate glass materials, boro-phosphosilicate glass materials, SiOC, spin-on-glass materials, spin-on-polymers or silicon carbon materials). In some embodiments, the dielectric layer 204E may be formed by spin-coating or deposition, including chemical vapor deposition (CVD), PECVD, HDP-CVD, or the like. In some embodiments, the metallization patterns 204D include under-metal metallurgies (UBMs). In some embodiments, the formation of the metallization patterns 204D may include patterning the dielectric layer using photolithography techniques and one or more etching processes and filling a metallic material into the openings of the patterned dielectric layer. Any excessive conductive material on the dielectric layer may be removed, such as by using a chemical mechanical polishing process. In some embodiments, the material of the metallization patterns 204D includes copper, aluminum, tungsten, silver, and combinations thereof. As illustrated in FIG. 19, a plurality of conductive terminals 126 are formed on and electrically connected to the metallization patterns 204D. In other words, the interconnection layer 204 (interposer structure) is electrically connected to the circuit substrate 300 through the conductive terminals 126.

In the package structure PK1H, the second semiconductor dies 112 with the reduced thickness are located at corners of the semiconductor package SM8. In other words, the semiconductor package SM8 of FIG. 19 has a top view that is similar to the semiconductor package SM1 illustrated in FIG. 12B. In the exemplary embodiment, the second semiconductor dies 112 are disposed on a first corner region R2, on a second corner region R2, a third corner region R2, and a fourth corner region R2 on the interconnection layer 104. Therefore, when bonding the semiconductor package SM8 onto the circuit substrate 300, the substrate contraction force can be counteracted, and a molding delamination risk at the corners of the insulating encapsulant 116′ can be reduced. Furthermore, in some embodiments, for heat dissipation of the first semiconductor dies 110 in the semiconductor package SM8, the backside surface 110-BS of the first semiconductor dies 110 are revealed from the insulating encapsulant 116′. In certain embodiments, a thermal insulating material (TIM) or a heat sink (not shown) may be further attached to the backside surface 110-BS of the first semiconductor dies 110. Overall, a package structure PK1H with improved reliability and improved heat dissipation can be achieved.

In the above-mentioned embodiments, the package structure includes first semiconductor dies and second semiconductor dies, whereby the second semiconductor dies are embedded in corners of the insulating encapsulant and located on corner regions of the interconnection layer. Since the second semiconductor dies with the reduced thickness are located at corners of the semiconductor package, when bonding the semiconductor package onto the circuit substrate, the substrate contraction force can be counteracted, and a molding delamination risk at the corners of the insulating encapsulant can be reduced. Overall, a package structure with improved reliability and improved heat dissipation can be achieved.

In accordance with some embodiments of the present disclosure, a package structure includes first semiconductor dies, second semiconductor dies, electrical connectors, an interconnection layer and an underfill structure. The first semiconductor dies are embedded in an insulating encapsulant, wherein backside surfaces of the first semiconductor dies are revealed by the insulating encapsulant. The second semiconductor dies are embedded in corners of the insulating encapsulant, wherein backside surfaces of the second semiconductor dies are covered by the insulating encapsulant. The electrical connectors are disposed on the first semiconductor dies and the second semiconductor dies. The interconnection layer is disposed on the insulating encapsulant and electrically connected to the first semiconductor dies and the second semiconductor dies through the electrical connectors. The underfill structure is disposed in between the first semiconductor dies, the second semiconductor dies and the interconnection layer, and laterally surrounding the electrical connectors.

In accordance with some other embodiments of the present disclosure, a package structure includes a circuit substrate, a semiconductor package and a stiffener ring. The semiconductor package is disposed on the circuit substrate and includes an interconnection layer, a plurality of conductive terminals, a plurality of first semiconductor dies, a plurality of second semiconductor dies, and an insulating encapsulant. The conductive terminals are electrically connecting the interconnection layer to the circuit substrate. The first semiconductor dies are disposed on a main region of the interconnection layer and electrically connected to the interconnection layer. The second semiconductor dies are disposed on corner regions of the interconnection layer and electrically connected to the interconnection layer, wherein the corner regions are surrounding the main region, and a thickness of the second semiconductor dies is smaller than a thickness of the first semiconductor die. The insulating encapsulant is disposed on the interconnection layer and encapsulating the first semiconductor dies and the second semiconductor dies. The stiffener ring is disposed on the circuit substrate and surrounding the semiconductor package.

In accordance with yet another embodiment of the present disclosure, a method of fabricating a package structure is described. The method includes the following steps. An interconnection layer is formed on a carrier. First semiconductor dies and second semiconductor dies are bonded to the interconnection layer, wherein the bonding includes electrically connecting the interconnection layer to the first semiconductor dies and the second semiconductor dies through a plurality of electrical connectors that are located on the first semiconductor dies and the second semiconductor dies. An underfill structure is formed in between the first semiconductor dies, the second semiconductor dies and the interconnection layer, and laterally surrounding the electrical connectors. An insulating encapsulant is formed to encapsulate the first semiconductor dies and the second semiconductor dies, wherein backside surfaces of the first semiconductor dies are revealed by the insulating encapsulant, and backside surfaces of the second semiconductor dies are covered by the insulating encapsulant.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A package structure, comprising:
at least one first semiconductor die embedded in an insulating encapsulant, wherein a backside surface of the at least one first semiconductor die is revealed by the insulating encapsulant;
a plurality of second semiconductor dies embedded in corners of the insulating encapsulant, wherein backside surfaces of the plurality of second semiconductor dies are covered by the insulating encapsulant;
a plurality of electrical connectors disposed on the at least one first semiconductor die and the plurality of second semiconductor dies;
an interconnection layer disposed on the insulating encapsulant and electrically connected to the at least one first semiconductor die and the plurality of second semiconductor dies through the plurality of electrical connectors; and
an underfill structure disposed in between the at least one first semiconductor die, the plurality of second semiconductor dies and the interconnection layer, and laterally surrounding the plurality of electrical connectors.

2. The package structure according to claim 1, wherein a width, a length and a thickness of the plurality of second semiconductor dies are smaller than a width, a length and a thickness of the at least one first semiconductor die.

3. The package structure according to claim 2, wherein the width and the length of the plurality of second semiconductor dies are greater than 2.2 mm.

4. The package structure according to claim 2, further comprising a plurality of third semiconductor dies, wherein a width and a length of the plurality of third semiconductor dies are equal to the width and the length of the plurality of second semiconductor dies, and wherein backside surfaces of the plurality of third semiconductor dies are revealed by the insulating encapsulant.

5. The package structure according to claim 1, wherein the plurality of second semiconductor dies are embedded in four corners of the insulating encapsulant.

6. The package structure according to claim 1, wherein the underfill structure entirely covers sidewalls of the plurality of second semiconductor dies that are facing sidewalls of the at least one first semiconductor die, and partially covers the sidewalls of the at least one first semiconductor die.

7. The package structure according to claim 6, wherein the underfill structure further covers and contact the backside surfaces of the plurality of second semiconductor dies.

8. The package structure according to claim 1, wherein the plurality of second semiconductor dies are embedded in two corners of the insulating encapsulant, and the at least one first semiconductor die includes a plurality of first semiconductor dies, and wherein a portion of the plurality of first semiconductor dies extend towards other corners of the insulating encapsulant.

9. A package structure, comprising:
a circuit substrate;
a semiconductor package disposed on the circuit substrate, wherein the semiconductor package comprises:
an interconnection layer;
a plurality of conductive terminals electrically connecting the interconnection layer to the circuit substrate;
at least one first semiconductor die disposed on a main region of the interconnection layer and electrically connected to the interconnection layer;
at least one second semiconductor die disposed on corner regions of the interconnection layer and electrically connected to the interconnection layer, wherein the corner regions are surrounding the main region, and a thickness of the at least one second semiconductor die is smaller than a thickness of the at least one first semiconductor die; and
an insulating encapsulant disposed on the interconnection layer and encapsulating the at least one first semiconductor die and the at least one second semiconductor die;
a stiffener ring disposed on the circuit substrate and surrounding the semiconductor package.

10. The package structure according to claim 9, wherein the corner regions of the interconnection layer includes a first corner region, a second corner region, a third corner region and a fourth corner region that are surrounding the main region, and wherein the at least one second semiconductor die includes a plurality of second semiconductor dies that are disposed on at least the first corner region and the third corner region.

11. The package structure according to claim 10, wherein the at least one first semiconductor die includes a plurality of first semiconductor dies, and a portion of the plurality of first semiconductor dies extends from the main region towards the second corner region and the fourth corner region on the interconnection layer.

12. The package structure according to claim 10, wherein no dies are located on the second corner region and the fourth corner region, and wherein the insulating encapsulant covers up the second corner region and the fourth corner region.

13. The package structure according to claim 9, further comprising:
a plurality of electrical connectors electrically connecting the at least one first semiconductor die and the at least one second semiconductor die to the interconnection layer; and
an underfill structure laterally surrounding the plurality of electrical connectors.

14. The package structure according to claim 13, wherein the underfill structure covers and contact the backside surfaces of the at least one second semiconductor die.

15. The package structure according to claim 9, further comprising a plurality of third semiconductor dies disposed aside the at least one first semiconductor die on the main region of the interconnection layer, wherein a thickness of the plurality of third semiconductor dies is equal to the thickness of the at least one first semiconductor die, and the plurality of third semiconductor dies and the at least one second semiconductor die are the same type of dies.

16. The package structure according to claim 9, wherein a backside surface of the at least one first semiconductor die is revealed by the insulating encapsulant, and a backside surface of the at least one second semiconductor die is covered by the insulating encapsulant.

17. A method of fabricating a package structure, comprising:
forming an interconnection layer on a carrier;
bonding at least one first semiconductor die and a plurality of second semiconductor dies to the interconnection layer, wherein the bonding comprises electrically connecting the interconnection layer to the at least one first semiconductor die and the plurality of second semiconductor dies through a plurality of electrical connectors that are located on the at least one first semiconductor die and the plurality of second semiconductor dies;
forming an underfill structure in between the at least one first semiconductor die, the plurality of second semiconductor dies and the interconnection layer, and laterally surrounding the plurality of electrical connectors; and
forming an insulating encapsulant encapsulating the at least one first semiconductor die and the plurality of second semiconductor dies, wherein a backside surface of the at least one first semiconductor die is revealed by the insulating encapsulant, and backside surfaces of the plurality of second semiconductor dies are covered by the insulating encapsulant.

18. The method according to claim 17, further comprising:
debonding the carrier to reveal a surface of the interconnection layer; and
forming a plurality of conductive terminals on the interconnection layer.

19. The method according to claim 17, further comprising bonding a plurality of third semiconductor dies, wherein a width and a length of the plurality of third semiconductor dies are equal to a width and a length of the plurality of second semiconductor dies, and wherein after forming the insulating encapsulant, backside surfaces of the plurality of third semiconductor dies are revealed by the insulating encapsulant.

20. The method according to claim 17, wherein after forming the underfill structure, the underfill structure entirely covers sidewalls of the plurality of second semiconductor dies that are facing sidewalls of the at least one first semiconductor die, and partially covers the sidewalls of the at least one first semiconductor die.
